(19) United States
(12) Patent Application Publication
(10) Pub. No.: US 2011/0043972 A1
(43) Pub. Date: Feb. 24, 2011

(54) PORTABLE ELECTRONIC DEVICE

(75) Inventor: JIN-TI CAO, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/607,295

(22) Filed: Oct. 28, 2009

(30) Foreign Application Priority Data
Aug. 19, 2009 (CN) 200920308333.5

(51) Int. Cl. H05K 5/00

(52) U.S. Cl. 361/679.01

(57) ABSTRACT

A portable electronic device is provided. The portable electronic device comprises a screen, a sliding housing, and a main housing. The screen is secured to the sliding housing. The sliding housing is slidably mounted to the main housing. The sliding housing comprises an adhesive area. A plurality of protrusions protrude from the sliding housing around the adhesive area. The protrusions restrict the screen within the adhesive area. The protrusions are formed integrally with the sliding housing.

### BACKGROUND

1. Technical Field

The present disclosure relates to portable electronic devices, particularly, to a portable electronic device with a sliding housing.

2. Description of Related Art

A portable electronic device with a sliding housing often includes a main housing, a sliding housing, and a sliding mechanism. The sliding housing may slide relative to the main housing using the sliding mechanism. The portable electronic device further includes a screen. A frame is secured to the sliding housing by welding. The screen is limited to positioning within the frame, thus requiring the mounting the screen to the sliding housing.

However, such screen securing means is complicated and increases manufacture cost.

Therefore, there is room for improvement within the art.

### BRIEF DESCRIPTION OF THE DRAWINGS

Many aspects of the portable electronic device can be better understood with reference to the following drawings. These drawings are not necessarily drawn to scale, the emphasis instead being placed upon clearly illustrating the principles of the present portable electronic device. Moreover, in the drawings like reference numerals designate corresponding sections throughout the several views.

FIG. 1 is an assembled, isometric view of a portable electronic device, in accordance with an exemplary embodiment.

FIG. 2 is an exploded, isometric view of a portable electronic device, in accordance with an exemplary embodiment.

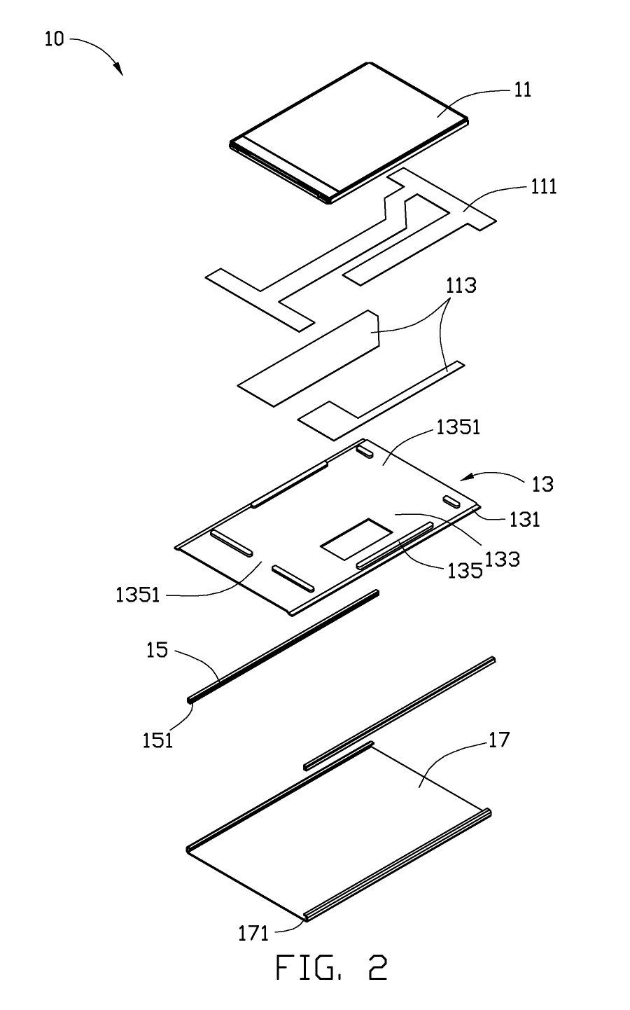

FIG. 3 is an isometric view of a sliding housing shown in FIG. 1.

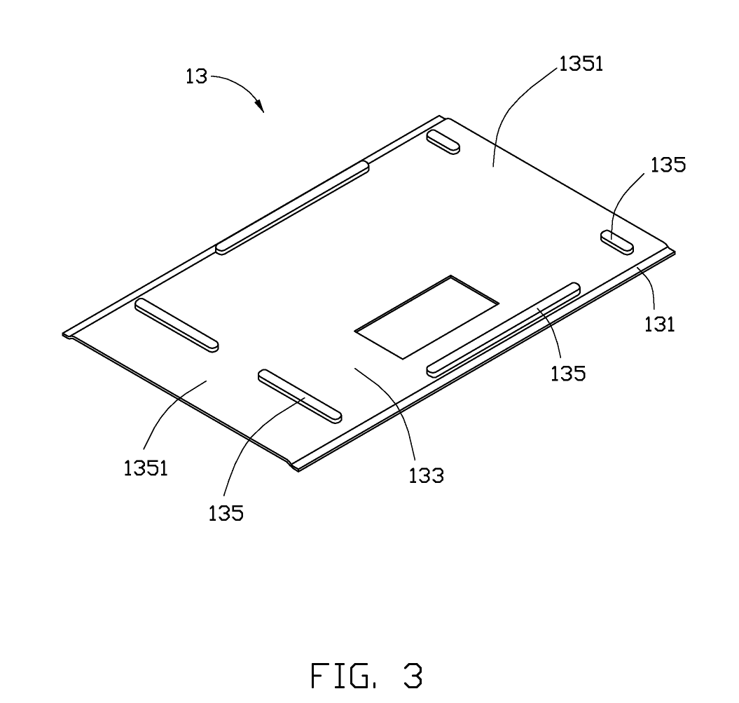

### DETAILED DESCRIPTION

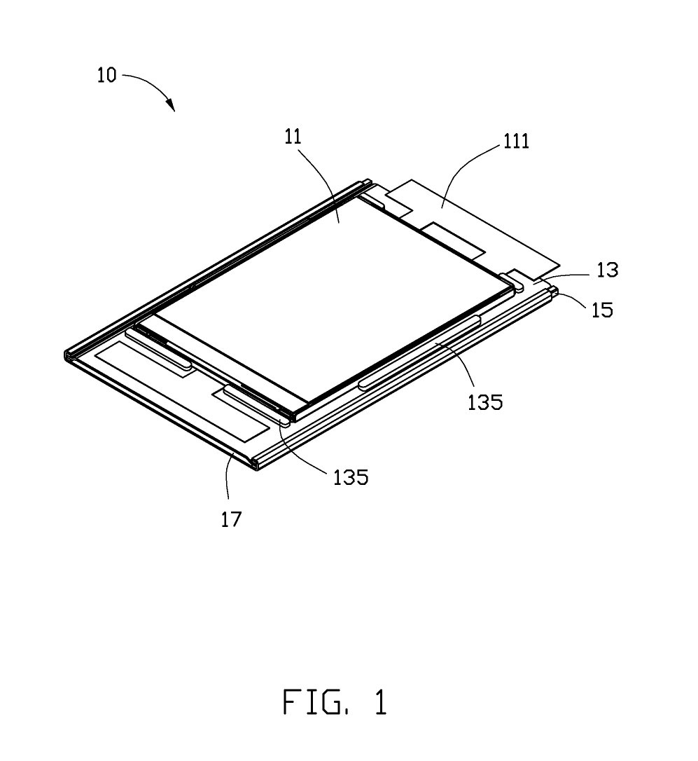

FIG. 1 shows an exemplary portable electronic device. The portable electronic device 10 includes a screen 11, a sliding housing 13, two rails 15, and a main housing 17. The screen 11 is secured to the sliding housing 13. The sliding housing 13 is engaged with the main housing 17 by the rails 15.

The screen 11 is electrically connected to a printed circuit board (PCB) by a cable 111. The screen 11 is adhered to the sliding housing 13 by two pieces of bond 113. In this embodiment, the bond 113 is a double-side adhesive.

The sliding housing 13 includes two sliding portions 131 formed on two opposite sides. The two sliding portions 131 slidably engage with the two rails 15. The sliding housing 13 further includes an adhesive area 133 between the two sliding portions 131. The size of the adhesive area 133 is generally as big as the screen 11. The screen 11 is adhered on the adhesive area 133. A plurality of protrusions 135 protrude from the sliding housing 13 around the adhesive area 133, used to secure the screen 11 within the adhesive area 133. In this embodiment, the protrusions 135 are integrally formed with the sliding housing 13. A plurality of channels 1351 are defined between every two protrusions 135. The cable 111 passes through the channels 1351 to electrically connect with the screen 11.

Each rail 15 defines a sliding slot 151, facing one sliding portion 131. The sliding portion 131 is slidably received in the sliding slot 151.

The main housing 17 defines two mounting cavities 171, corresponding to the two rails 15. The two mounting cavities 171 are respectively located at two opposite ends of the main housing 17, and each of which is used to mount a corresponding rail 15.

In assembly, the two rails 15 are each mounted in a mounting cavity 171. The two sliding portions 131 are each inserted into the two sliding slots 151, thus the sliding housing 13 can slide relative to the rails 15. The cable 111 is secured to the sliding housing 13, with one end of the cable 111 in the adhesive area 133. The screen 11 is adhered on the adhesive area 133, with the cable 111 electrically connected to the screen 11.

The present portable electronic device 10 includes the protrusions 135 formed with the sliding housing 13 in integrally-forming method, which is relatively simple and decreases manufacture cost.

It is to be understood, however, that even through numerous characteristics and advantages of the present disclosure have been set forth in the foregoing description, together with details of the structure and function of the disclosure, the disclosure is illustrative only, and changes may be made in detail, especially in matters of shape, size, and arrangement of sections within the principles of the disclosure to the full extent indicated by the broad general meaning of the terms, in which the appended claims are expressed.

What is claimed is:

1. A portable electronic device comprising:
a screen;
a sliding housing, the screen being secured to the sliding housing, the sliding housing comprising an adhesive area, a plurality of protrusions protruding from the sliding housing around the adhesive area, the protrusions restricting the screen within the adhesive area, the protrusions being formed integrally with the sliding housing; and
a main housing, the sliding housing slidably mounted to the main housing.

2. The portable electronic device as claimed in claim 1, further comprising two rails, the sliding housing is engaged with the main housing by the rails.

3. The portable electronic device as claimed in claim 1, wherein the screen is adhered to the sliding housing.

4. The portable electronic device as claimed in claim 1, further comprising a cable, wherein a plurality of channels are defined between two protrusions, the cable is electrically connected to the screen through the channels.

5. The portable electronic device as claimed in claim 2, wherein the sliding housing includes two sliding portions, each rail defines a sliding slot, the sliding portions are slidably engaged with the sliding slots.

6. The portable electronic device as claimed in claim 2, wherein the main housing includes two mounting cavities, corresponding to the two rails, the two mounting cavities are opposite to each other for mounting a corresponding rail.

7. A portable electronic device comprising:
a screen;
a sliding housing, the sliding housing comprising an adhesive area, a plurality of protrusions being formed integrally with the sliding housing and around the adhesive area, the protrusions restricting the screen within the adhesive area.

8. The portable electronic device as claimed in claim 7, wherein the screen is adhered to the sliding housing.

9. The portable electronic device as claimed in claim 7, further comprising a cable, wherein a plurality of channels are defined between two protrusions, the cable is electrically connected to the screen through the channels.
